(19) United States
(12) Patent Application Publication
(10) Pub. No.: US 2015/0270813 A1
(43) Pub. Date: Sep. 24, 2015

(54) DYNAMICALLY ADJUSTABLE POWER AMPLIFIER LOAD TUNER

(71) Applicant: QUALCOMM Incorporated, San Diego, CA (US)

(72) Inventors: Ali Morshedi, San Diego, CA (US); Robert LIoyd Robinett, San Diego, CA (US); Madhavan Srinivasan Vajapeyam, San Diego, CA (US)

(73) Assignee: QUALCOMM Incorporated, San Diego, CA (US)

(21) Appl. No.: 14/220,772

(22) Filed: Mar. 20, 2014

(51) Int. Cl. H03F 1/56; H04B 17/19; H03F 3/21

(52) U.S. Cl. CPC H03F 1/56; H03F 3/21; H04B 17/19; H03F 2200/255

(57) ABSTRACT

An apparatus includes a power amplifier and a power amplifier load tuner. The power amplifier load tuner includes multiple input ports. A first input port of the power amplifier load tuner is selectively coupled to a corresponding power amplifier. The power amplifier load tuner has an adjustable impedance.

### I. FIELD

The present disclosure is generally related to a dynamically adjustable power amplifier load tuner.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

A wireless telephone may receive and transmit signals at a transceiver. The transceiver may include multiple filters that are tuned to different frequency bands. Each filter may be coupled to a corresponding load that includes multiple components (e.g., capacitors, inductors, resistors, etc.) to generate a load impedance for each frequency band. Digital pre-distortion and envelope tracking at a power amplifier may be based on a particular impedance of each load. Envelope tracking may require impedance matching between each filter and a corresponding power amplifier due to the non-linearity associated with transmissions and emissions. Impedance matching may include tuning components of the load to enhance transmission metrics (e.g., power added efficiency (PAE), linearity, output power, adjacent channel leakage ratio (ACLR), etc.). Impedance matching may vary an impedance of the load based on a transmission frequency within a frequency band, a bandwidth, and/or temperature. Having multiple components for each frequency band (e.g., for each filter) results in use of a relatively large circuit area for such components. Further, tuning to improve performance for particular transmission metrics at a particular frequency band may reduce performance of other transmission metrics at the particular frequency band.

### III. BRIEF DESCRIPTION OF THE DRAWINGS

FIG. 1 shows a wireless device communicating with a wireless system;

FIG. 2 shows a block diagram of the wireless device in FIG. 1;

FIG. 3 is a diagram that depicts an exemplary embodiment of a system that includes a power amplifier load tuner having a dynamically adjustable impedance;

FIG. 4 is a diagram that depicts another exemplary embodiment of a system that includes a power amplifier load tuner having a dynamically adjustable impedance;

FIG. 5 is a diagram that depicts an exemplary embodiment of a chip that includes a power amplifier load tuner having a dynamically adjustable impedance;

FIG. 6 is a diagram that depicts an exemplary embodiment of a power amplifier load tuner having a dynamically adjustable impedance;

FIG. 7 is a diagram that depicts an exemplary embodiment of a wireless communications system;

FIG. 8 is a diagram of a Smith chart that illustrates advantages of a power amplifier load tuner having a dynamically adjustable impedance; and

FIG. 9 is a flowchart that illustrates an exemplary embodiment of a method for adjusting an impedance of a power amplifier load tuner.

### IV. DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

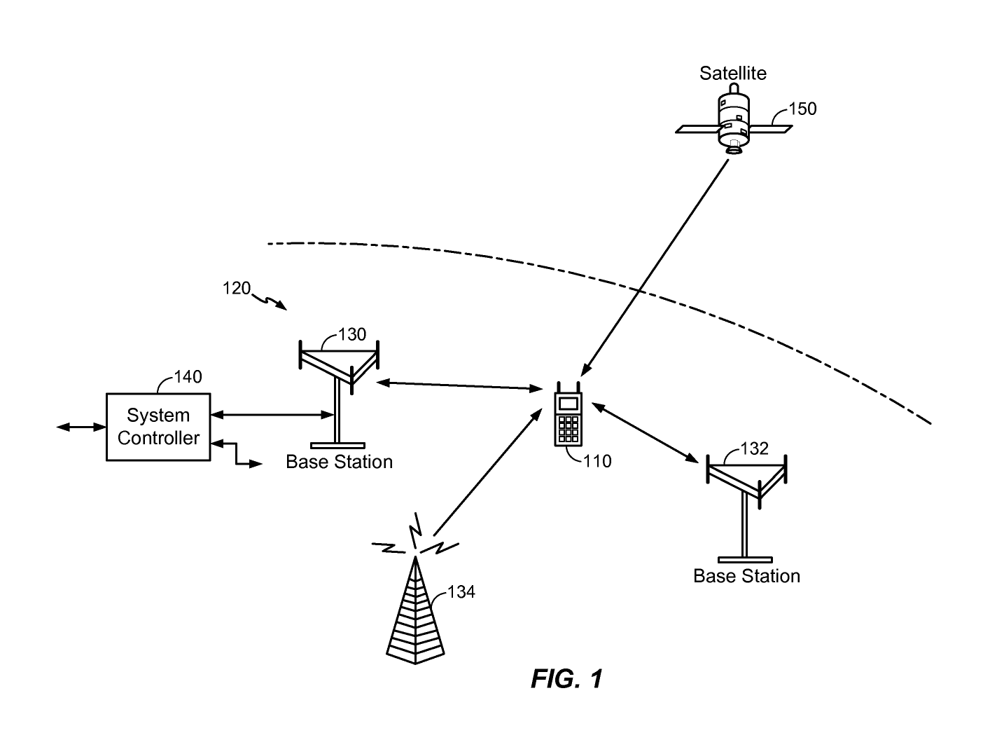

FIG. 1 shows a wireless device 110 communicating with a wireless communication system 120. Wireless communication system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless system may include any number of base stations and any set of network entities.

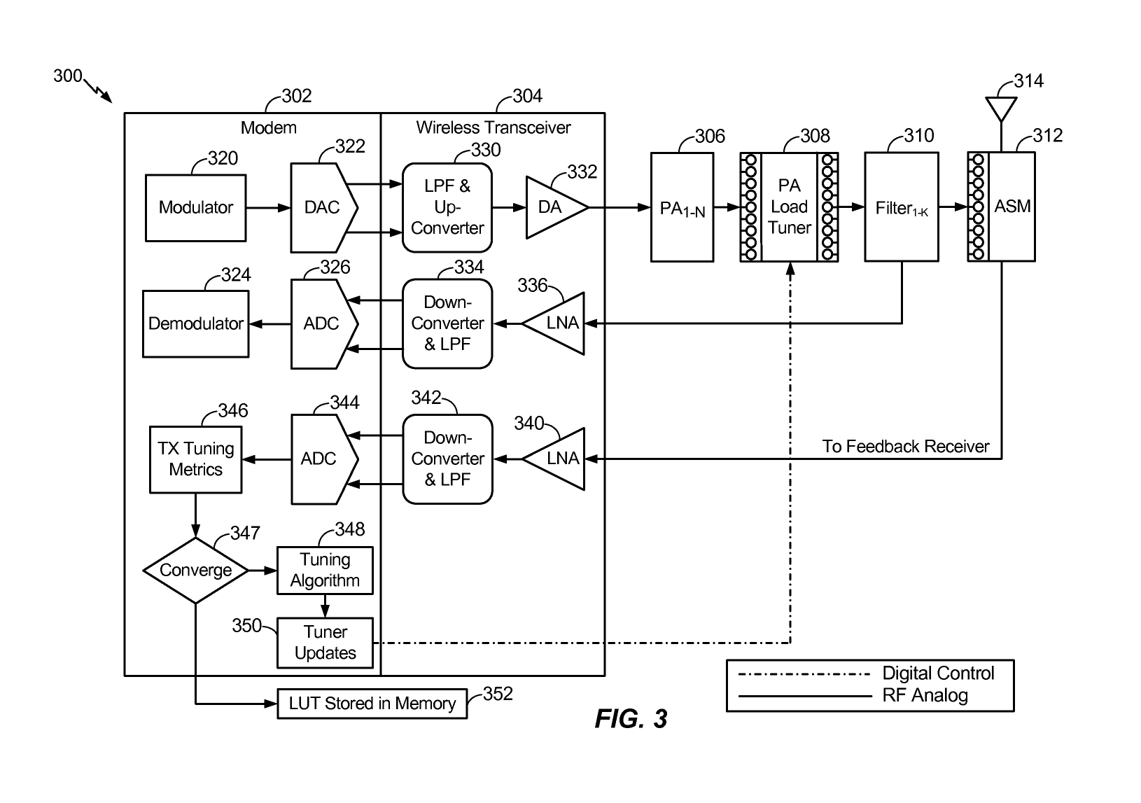

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1x, EVDO, TD-SCDMA, GSM, 802.11, etc. In an exemplary embodiment, the wireless device 110 may include a power amplifier load tuner having a dynamically adjustable impedance, as described below with respect to FIGS. 3-6.

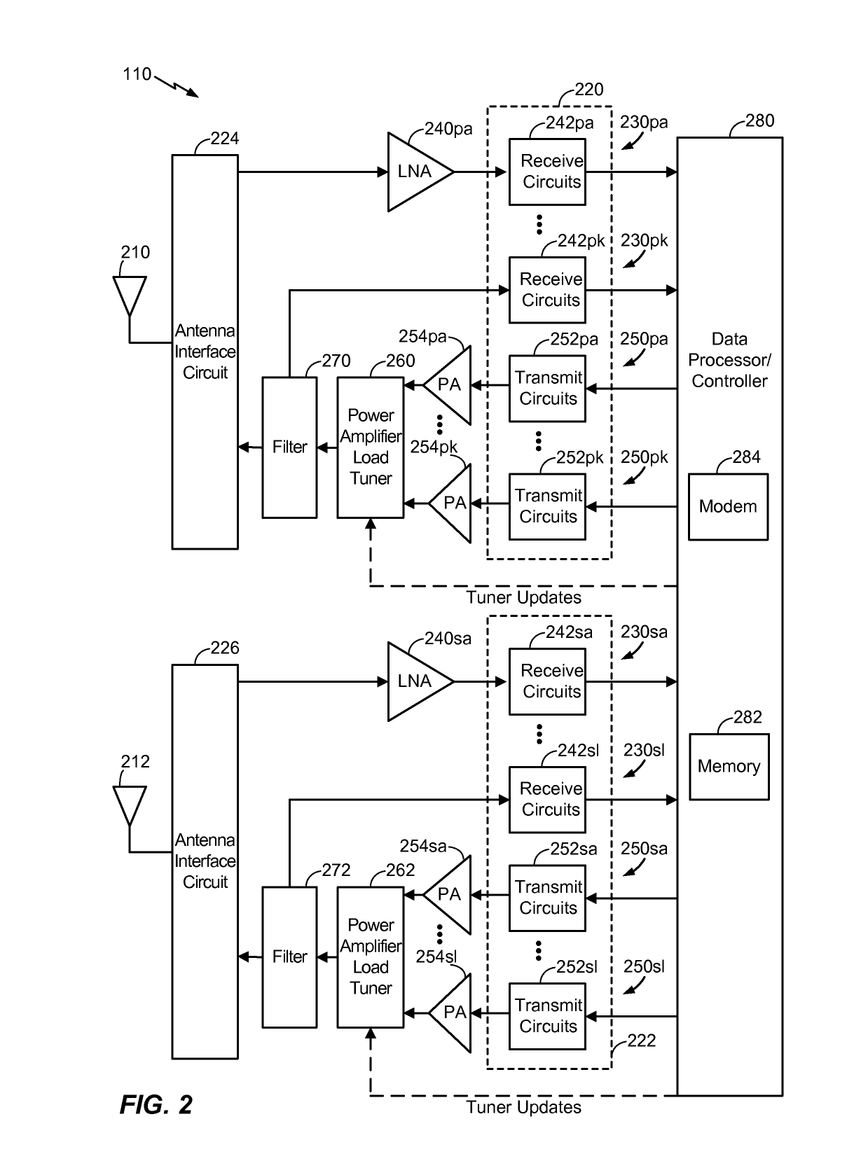

FIG. 2 shows a block diagram of an exemplary design of wireless device 110 in FIG. 1. In this exemplary design, wireless device 110 includes a transceiver 220 coupled to a primary antenna 210, a transceiver 222 coupled to a secondary antenna 212, and a data processor/controller 280. Transceiver 220 includes multiple (K) receivers 230pa to 230pk and multiple (K) transmitters 250pa to 250pk to support multiple frequency bands, multiple radio technologies, carrier aggregation, etc. Transceiver 222 includes multiple (L) receivers 230sa to 230sl and multiple (L) transmitters 250sa to 250sl to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230pa, 230pk, 230sa, 230sl includes an LNA 240pa, 240sa and receive circuits 242pa, 242pk, 242sa, 242sl. The LNA for receiver 230pk may be within the receive circuit 242pk, and the LNA for receiver 230sl may be within the receive circuit 242sl. In an exemplary embodiment, a first feedback LNA (not shown) is in the receive circuit 242pk and a second feedback LNA (not shown) is in the receive circuit 242sl. For data reception, the antenna 210 receives signals from base stations and/or other transmitter stations and provides a received RF signal, which is routed through an antenna interface circuit 224 and presented as an input RF signal to a selected receiver. Antenna interface circuit 224 may include switches, duplexers, transmit filters, receive filters, matching circuits, etc. The description below assumes that receiver 230pa is the selected receiver. Within receiver 230pa, an LNA 240pa amplifies the input RF signal and provides an output RF signal. Receive circuits 242pa downconvert the output RF signal from RF to baseband, amplify and filter the downconverted signal, and provide an analog input signal to data processor 280. Receive circuits 242pa may include mixers, filters, amplifiers, matching circuits, an oscillator, a local oscillator (LO) generator, a phase locked loop (PLL), etc. Each remaining receiver 230 in transceivers 220 and 222 may operate in similar manner as receiver 230pa.

In the exemplary design shown in FIG. 2, each transmitter 250 includes transmit circuits 252 and a power amplifier (PA) 254. For data transmission, data processor 280 processes (e.g., encodes and modulates) data to be transmitted and provides an analog output signal to a selected transmitter. The description below assumes that transmitter 250pa is the selected transmitter. Within transmitter 250pa, transmit circuits 252pa amplify, filter, and upconvert the analog output signal from baseband to RF and provide a modulated RF signal. Transmit circuits 252pa may include amplifiers, filters, mixers, matching circuits, an oscillator, an LO generator, a PLL, etc. A PA 254pa receives and amplifies the modulated RF signal and provides a transmit RF signal having the proper output power level. The transmit RF signal is routed through a power amplifier load tuner 260, a filter 270, and an antenna interface circuit 224 and transmitted via antenna 210. Each remaining transmitter 250 in transceivers 220 and 222 may operate in similar manner as transmitter 250pa. For example, a transmit RF signal from the transmit circuit 252sl may be routed through a power amplifier load tuner 262, a filter 272, and an antenna interface 226 circuit and transmitted via antenna 212.

In an exemplary embodiment, the impedance of each of the power amplifier load tuners 260, 262 may be adjustable based on a digital signal (e.g., tuner updates) provided from a modem 284 within the data controller 280. For example, the transmit RF signals may be provided to the first and second feedback LNAs in the receive circuits 242pk, 242sl from the filters 270, 272, respectively, via feedback paths. The modem 284 may determine transmission metrics of the transmit RF signals and adjust the impedance of the power amplifier load tuners 260, 262 based on the transmission metrics. For example, the modem may determine to adjust the impedance of the power amplifier load tuners 260, 262 to improve at least one of adjacent channel leakage ratio (ACLR), power added efficiency (PAE), output power, error vector magnitude (EVM), or gain. Each power amplifier load tuner 260, 262 may include a controller coupled to receive digital tuning signals (e.g., the tuner updates) from the modem 284 based on feedback (from the filters 270, 272) associated with characteristics of a transmission signal, as explained in greater detail with respect to FIG. 3.

FIG. 2 shows an exemplary design of receiver 230 and transmitter 250. A receiver and a transmitter may also include other circuits not shown in FIG. 2, such as filters, matching circuits, etc. All or a portion of transceivers 220 and 222 may be implemented on one or more analog integrated circuits (ICs), RF ICs (RFICs), mixed-signal ICs, etc. For example, LNAs 240 and receive circuits 242 may be implemented on one module, which may be an RFIC, etc. The circuits in transceivers 220 and 222 may also be implemented in other manners.

Data processor/controller 280 may perform various functions for wireless device 110. For example, data processor 280 may perform processing for data being received via receivers 230 and data being transmitted via transmitters 250. Controller 280 may control the operation of the various circuits within transceivers 220 and 222. A memory 282 may store program codes and data for data processor/controller 280. Data processor/controller 280 may be implemented on one or more application specific integrated circuits (ASICs) and/or other ICs.

Wireless device 110 may support multiple band groups, multiple radio technologies, and/or multiple antennas. Wireless device 110 may include a number of LNAs to support reception via the multiple band groups, multiple radio technologies, and/or multiple antennas.

Referring to FIG. 3, an exemplary embodiment of a system 300 that includes a power amplifier load tuner having a dynamically adjustable impedance is shown. In an exemplary embodiment, the system 300 may be implemented within the wireless device 110 of FIGS. 1-2. The system 300 includes a modem 302, a wireless transceiver 304, power amplifiers 306_{1-N}, a power amplifier load tuner 308, and filters 310_{1-K}. In an exemplary embodiment, the wireless transceiver 304 may correspond to the transceivers 220, 222 in FIG. 2 and the modem 302 may correspond to the modem 284 of FIG. 2. In an exemplary embodiment, N and K are any integer values greater than zero. As a non-limiting example, if N is equal to twenty and K is equal to twenty-five, the system 300 may include twenty power amplifiers 306 and twenty-five filters 310. In another exemplary embodiment, N and K may correspond to the same integer value. For example, if N and K are each equal to twenty, the system 300 may include twenty power amplifiers 306 and twenty filters 310. In an exemplary embodiment, the power amplifier load tuner 308 corresponds to one or more of the power amplifier load tuners 260, 262 of FIG. 2 and the filters 310_{1-K} corresponds to one or more of the filters 270, 272 of FIG. 2.

The modem 302 may include a modulator 320 coupled to a digital-to-analog converter 322. The modulator 320 and the digital-to-analog converter 322 may be included within a transmission path (e.g., transmission circuitry). The modulator 320 may be configured to modulate a carrier signal with a modulated signal (e.g., a digital signal bit stream) and provide the resulting signal to the digital-to-analog converter 322. The digital-to-analog converter 322 may be configured to convert the resulting signal from a digital signal into an analog signal.

The wireless transceiver 304 may include a low pass filter and up-converter 330 and a driver amplifier 332. The low pass filter and up-converter 330 and the driver amplifier 332 may also be included in the transmission path. The low pass filter and up-converter 330 may filter particular frequencies of the analog signal provided from the digital-to-analog converter 322. The low pass filter and up-converter 330 may also up-convert the analog signal from a baseband frequency signal (or intermediate frequency signal) to a radio frequency signal (e.g., an up-converted signal). The up-converted signal may be provided to the driver amplifier 332. The driver amplifier 332 (e.g., an intermediate amplifier) may be configured to amplify the up-converted signal and provide the amplified up-converted signal to the power amplifiers 306.

Each power amplifier 306 may be configured to amplify the analog signal received from the driver amplifier 332. The amplified signals may be provided to the power amplifier load tuner 308. Each power amplifier 306 may be associated with a distinct transmission frequency and may be selectively coupled to the power amplifier load tuner 308 based on the transmission frequency. For example, in an exemplary embodiment, an active power amplifier (e.g., a power amplifier associated with a frequency band in which signals are to be transmitted) may be coupled to the power amplifier load tuner 308 via a switch (e.g., a multiplexer), and inactive power amplifiers (e.g., power amplifiers associated with frequency bands in which signals are not being transmitted) may be decoupled from the power amplifier load tuner 308 via the switch. In another exemplary embodiment, each power amplifier 306 may be associated with a distinct transmission frequency and temperature. For example, each power amplifier 306 may be configured to transmit over an uplink bandwidth using resource blocks within the uplink bandwidth.

The power amplifier load tuner 308 may include multiple input ports. Each input port of the power amplifier load tuner 308 may be associated with a distinct frequency and may be selectively coupled to a corresponding power amplifier 306. As a non-limiting example, the system 300 may include twenty power amplifiers 306 (N=20) (e.g., a first power amplifier 306₁, a second power amplifier 306₂, a third power amplifier 306₃, etc.) and the power amplifier load tuner 308 may include twenty input ports (e.g., a first input port, a second input port, a third input port, etc.). Each power amplifier 306 may be selectively coupled to the corresponding input port based on the transmission frequency of the system 300. For example, the first power amplifier 306₁ may be coupled to the first input port via the switch when transmission signals are to be transmitted over a first transmission frequency, the second power amplifier 306₂ may be coupled to the second input port via the switch when transmission signals are to be transmitted over a second transmission frequency, etc.

An impedance of the power amplifier load tuner 308 may be adjustable based on a selected input port and at least one metric associated with a frequency of the selected input port. For example, the power amplifier load tuner 308 may include a controller coupled to receive a digital tuning signal based on feedback associated with characteristics of a transmission signal. The controller may be configured to adjust the impedance of the power amplifier load tuner 308 based on the digital tuning signal. For example, in an exemplary embodiment, the power amplifier load tuner 308 may include at least one capacitor bank and/or at least one inductor. Based on the digital tuning signal, the controller may selectively activate (or deactivate) at least one capacitor of the at least one capacitor bank and/or may selectively activate the at least one inductor to adjust the impedance of the power amplifier load tuner 308.

The power amplifier load tuner 308 may also include multiple output ports. In an exemplary embodiment indicative of synchronous port selection, the number of output ports may correspond to the number of input ports of the power amplifier load tuner 308. Each output port may be selectively coupled to a corresponding filter 310 via a switch (e.g., a multiplexer). For example, a first filter 310₁ may be tuned to the first transmission frequency, a second filter 310₂ may be tuned to the second transmission frequency, etc. A first output port of the power amplifier load tuner 308 may be selectively coupled to the first filter 310₁ via the switch, a second output port of the power amplifier load tuner 308 may be selectively coupled to the second filter 310₂ via the switch, etc.

In the exemplary embodiment indicative of synchronous port selection, the first output port of the power amplifier load tuner 308 may be coupled to the first filter 310₁ via the switch when the first input port of the power amplifier load tuner 308 is coupled to the first power amplifier 306₁ to enable a transmission signal that is amplified by the first power amplifier 306₁ to be filtered by the first filter 310₁ (e.g., filtered based on the first transmission frequency). In a similar manner, the second output port of the power amplifier load tuner 308 may be coupled to the second filter 310₂ via the switch when the second input port of the power amplifier load tuner 308 is coupled to the second power amplifier 306₂ to enable a transmission signal that is amplified by the second power amplifier 306₂ to be filtered by the second filter 310₂, etc.

In an exemplary embodiment indicative of asynchronous port selection, an input port of the power amplifier load tuner 308 may be active (e.g., coupled to a corresponding power amplifier 306) and a non-corresponding output port of the power amplifier load tuner 308 may be active. For example, the first power amplifier 306₁ may be coupled to the power amplifier load tuner 308 via the first input port of the power amplifier load tuner 308, and the first or second filter 310₁-310₂ may be coupled to the first or second output port of the power amplifier load tuner 308, respectively, to enable asynchronous port selection. Thus, the first power amplifier 306₁ may transmit over two or more frequency bands (e.g., a frequency band associated with the first filter 310₁ or a frequency band associated with the second filter 310₂) to reduce the number of passive matching components in the power amplifier load tuner 308.

Outputs of the filters 310 may be provided to an antenna switching module 312. The antenna switching module 312 may enable signal transmission over a wireless network via an antenna 314 and/or may enable an output of the filters 310 (e.g., a transmission signal) to be provided to a feedback receiver, as described below.

The system 300 may also include a reception path (e.g., reception circuitry) to process received signals. For example, the reception path may include a low noise amplifier 336, a down-converter and low pass filter 334, an analog-to-digital converter 326, and a demodulator 324. The low noise amplifier 336 and the down-converter and low pass filter 334 may be included in the wireless transceiver 304, and the demodulator 324 and the analog-to-digital converter 326 may be included in the modem 302.

During signal reception, radio frequency signals may be received via the antenna 314 and provided to the filters 310 via the antenna switching module 312. The filters 310 may be configured to filter the received radio frequency signals, and a resulting signal may be provided to the low noise amplifier 336. The low noise amplifier 336 may be configured to amplify and adjust the gain of the filtered signals. The output signals of the low noise amplifier 336 may be down-converted and filtered by the down-converter and low pass filter 334. The output of the down-converter and low pass filter 334 may be converted into a digital signal via the analog-to-digital converter 326, and the output of the analog-to-digital converter 326 may be demodulated by the demodulator 324.

As explained above, the antenna switching module 312 may enable the transmission signal to be provided to the feedback receiver. The feedback receiver may include a low noise amplifier 340, a down-converter and low pass filter 342, and an analog-to-digital converter 344. The low noise amplifier 340 may be configured to amplify and adjust the gain of the transmission signal from the transmission path, the down-converter and low pass filter 342 may be configured to down-convert and filter the output of the low noise amplifier 340, and the analog-to-digital converter 344 may be configured to convert the output of the down-converter and low pass filter 342 into a digital feedback signal (e.g., a digital signal representative of the transmission signal from the transmission circuitry). Although feedback to the feedback receiver is enabled using the antenna switching module 312, in other exemplary embodiments, other components may enable feedback to the feedback receiver. For example, a coupler may be placed on the transmission path to enable feedback to the feedback receiver.

The modem 302 may be configured to determine transmission tuning metrics 346 of the transmission signal based on the digital feedback signal. For example, the modem 302 may be configured to determine a power added efficiency of the transmission signal, a linearity of the transmission signal, an adjacent channel leakage ratio of the transmission signal, an output power of the transmission signal, an error vector magnitude associated with the transmission signal, or any combination thereof.

During an on-line process (e.g., when the modem 302 is connected to a wireless network), the modem 302 may be configured to determine whether one or more of the transmission tuning metrics 346 satisfy a threshold. For example, based on the particular power amplifier 306 coupled to the power amplifier load tuner 308 (e.g., based on the transmission frequency), the modem 302 may determine whether at least one of the transmission tuning metrics 346 satisfy an associated threshold. To illustrate, the modem 302 may determine whether the power added efficiency of the transmission signal at a particular frequency (e.g., when a particular power amplifier 306 and corresponding filter 310 is coupled to the power amplifier load tuner 308) satisfies a power added efficiency threshold based on information associated with the digital feedback signal. Although the following example is described with respect to power added efficiency, it will be appreciated that tuning based on other transmission tuning metrics 346 (e.g., linearity, adjacent channel leakage ratio, output power, error vector magnitude, etc.) may be performed.

If the power added efficiency of the transmission signal at the particular frequency satisfies the power added efficiency threshold, the modem 302 may converge the tuning values of the power amplifier load tuner 308 as the tuning value for power added efficiency, at 347, and may store the tuning values of the power amplifier load tuner 308 in a lookup table of a memory 352. For example, the modem 302 may store information associated with a number of active capacitors and/or a number of active inductors in the power amplifier load tuner 308 in the lookup table of the memory 352. In an exemplary embodiment, a controller in the power amplifier load tuner 308 may provide a digital signal to the modem 302 to indicate the number of active capacitors and/or active inductors in the power amplifier load tuner 308. The tuning values stored in the lookup table of the memory 352 may be accessed when the modem 302 is off-line (e.g., when the modem 302 is disconnected from a wireless network) to tune (e.g., calibrate) the power amplifier load tuner 308 to a desired impedance for power added efficiency.

If the power added efficiency of the transmission signal at the particular frequency fails to satisfy the power added efficiency threshold, the modem 302 may input the power added efficiency into a tuning algorithm 348 to determine updated tuning values 350. In an exemplary embodiment, the tuning algorithm 348 may correspond to the Nelder-Mead algorithm. For example, the tuning algorithm 348 may extrapolate behavior of the digital feedback signal for a particular transmission metric to determine tuning values 350 (e.g., capacitance values and/or inductance values) based on the behavior. To illustrate, the tuning algorithm 348 may select settings to be applied in the power amplifier load tuner 308, such as variable capacitance settings and/or switch settings. As another example, the tuning algorithm 348 may determine one or more impedance values that are provided to the power amplifier load tuner 308, and the controller in the power amplifier load tuner 308 may select settings based on the received impedance values. The updated tuning values 350 may be provided to the controller of the power amplifier load tuner 308 as a signal (e.g., a digital signal), and the controller may selectively activate (or deactivate) capacitors and/or inductors of the power amplifier load tuner 308 based on the updated tuning values 350. The transmission signal based on the updated tuning values 350 may be provided to the feedback receiver to determine whether the power added efficiency (e.g., the transmission tuning metrics 346) of the transmission signal satisfies the power added efficiency threshold. If the power added efficiency satisfies the power added efficiency threshold, the modem 302 may converge the tuning values of the power amplifier load tuner 308 as the tuning value for power added efficiency, at 347, and may store the tuning values of the power amplifier load tuner 308 in the lookup table of the memory 352. If the power added efficiency fails to satisfy the power added efficiency threshold, the modem 302 may input the power added efficiency into the tuning algorithm 348 to determine updated tuning values 350 as an iterative process in a substantially similar manner as described above.

In an exemplary embodiment, during an off-line process (e.g., when the modem 302 is disconnected from a wireless network), the system 300 may populate the lookup table stored in the memory 352 based on calibration transmission tuning metric values. For example, the system 300 may populate the lookup table stored in the memory 352 for each transmission tuning metric (e.g., power added efficiency, linearity, adjacent channel leakage ratio, output power, error vector magnitude, etc.) during calibration or characterization. As explained above, the modem 302 may determine whether one or more of the transmission tuning metrics 346 satisfy a threshold during the on-line process and may adjust the impedance of the power amplifier load tuner 308 based on the determination.

In another exemplary embodiment, the system 300 is self-adjusting and the modem 302 sets the modulator 320 for a continuous wave output setting. For example, a self test transmit signal (e.g., a CDMA2000 transmit pilot signal, a WCDMA transmit pilot signal, and/or a test signal for other wireless technologies supported by the modem 302) may be generated by the modem 302. The system 300 may use a reference tone to measure the feedback receiver residual sideband (e.g., measure the in-phase and quadrature imbalance) and the feedback receiver linearity. The modem 302 may use the measurements to determine the transmission tuning metrics of the power amplifier 306. For example, the feedback receiver residual sideband may indicate an output power of the power amplifier 306.

The system 300 of FIG. 3 may enable dynamic adjustment of the power amplifier load tuner 308 based on use cases (e.g., modes of operations such as voice communications, data communications, etc.). For example, during voice communications, the system 300 may dynamically adjust the impedance (e.g., the number of active capacitors and/or active inductors in the power amplifier load tuner 308) to improve power added efficiency. During data communications, the system 300 may dynamically adjust the impedance to improve adjacent channel leakage ratio, output power, and linearity. Further, during voice applications with relatively strong data throughput (e.g., global positioning system (GPS) applications), the system 300 may dynamically adjust the impedance to a “compromise” point to achieve relatively high power added efficiency, adjacent channel leakage ratio, output power, and linearity.

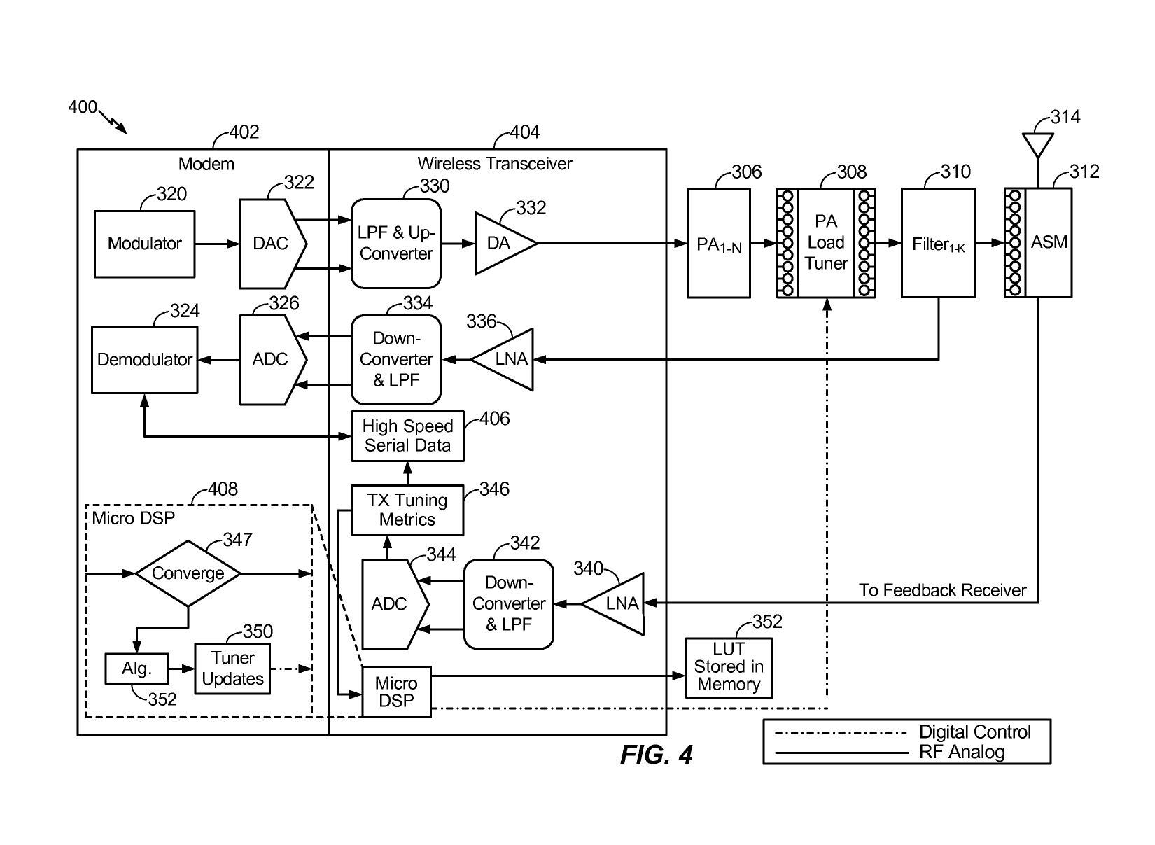

Referring to FIG. 4, another exemplary embodiment of a system 400 that includes a power amplifier load tuner having a dynamically adjustable impedance is shown. In an exemplary embodiment, the system 400 may be implemented in the wireless device 110 of FIGS. 1-2. The system 400 includes a modem 402, a wireless transceiver 404, the power amplifiers 306_{1-N}, the power amplifier load tuner 308, and the filters 310_{1-N}.

The modem 402 may include the modulator 320, the digital-to-analog converter 322, the demodulator 324, and the analog-to-digital converter 326. The wireless transceiver 404 may include the low pass filter and up-converter 330, the driver amplifier 332, down-converter and low pass filter 334, and the low noise amplifier 336. The modulator 320, the digital-to-analog converter 322, the low pass filter and up-converter 330, and the driver amplifier 332 may be included within a transmission path and may operate in a substantially similar manner as described with respect to FIG. 3. The demodulator 324, the analog-to-digital converter 326, the down-converter and low pass filter 334, and the low noise amplifier 3336 may be included within a reception path and may operate in a substantially similar manner as described with respect to FIG. 3.

The power amplifiers 306, the power amplifier load tuner 308, the filters 310, the antenna switching module 312, and the antenna 314 may also operate in a substantially similar manner as described with respect to FIG. 3. The wireless transceiver 404 may also include a feedback receiver. The feedback receiver may include the low noise amplifier 340, the down-converter and low pass filter 342, the analog-to-digital converter 344, and a micro digital signal processor 408. The wireless transceiver 404 may determine the transmission tuning metrics 346 based on the digital feedback signal (e.g., the output of the analog-to-digital converter 344).

The micro digital signal processor 408 may be configured to determine whether one or more of the transmission tuning metrics 346 satisfy a threshold. For example, based on the particular power amplifier 306 coupled to the power amplifier load tuner 308 (e.g., based on the transmission frequency), the micro digital signal processor 408 may determine whether at least one of the transmission tuning metrics 346 satisfy an associated threshold. To illustrate, the micro digital signal processor 408 may determine whether the adjacent channel leakage ratio of the transmission signal at a particular frequency (e.g., when a particular power amplifier 306 and corresponding filter 310 is coupled to the power amplifier load tuner 308) satisfies an adjacent channel leakage ratio threshold based on information associated with the digital feedback signal. Although the following example is described with respect to adjacent channel leakage ratio, it will be appreciated that tuning based on other transmission tuning metrics 346 (e.g., linearity, power added efficiency, output power, error vector magnitude, etc.) may be performed.

If the adjacent channel leakage ratio of the transmission signal at the particular frequency satisfies the adjacent channel leakage ratio threshold, micro digital signal processor 408 may converge the tuning values of the power amplifier load tuner 308 as the tuning value for adjacent channel leakage ratio, at 347, and may store the tuning values of the power amplifier load tuner 308 in a lookup table of a memory 452. For example, the micro digital signal processor 408 may store information associated with a number of active capacitors and/or a number of active inductors in the power amplifier load tuner 308 in the lookup table of the memory 452. The controller in the power amplifier load tuner 308 may provide a digital signal to the micro digital signal processor 408 to indicate the number of active capacitors and/or active inductors in the power amplifier load tuner 308. In an exemplary embodiment, the memory 452 may be located in the wireless transceiver 404. In another exemplary embodiment, the memory 452 may be located in the modem 402 and may be accessed by a high speed serial data interface 406. The tuning values stored in the lookup table of the memory 452 may be accessed to tune (e.g., calibrate) the power amplifier load tuner 308 to a desired impedance for adjacent channel leakage ratio.

If the adjacent channel leakage ratio of the transmission signal at the particular frequency fails to satisfy the adjacent channel leakage ratio threshold, the micro digital signal processor 408 may input the adjacent channel leakage ratio into a tuning algorithm 348 to determine updated tuning values 350. The updated tuning values 350 may be provided to the controller of the power amplifier load tuner 308 as a digital signal, and the controller may selectively activate (or deactivate) capacitors and/or inductors of the power amplifier load tuner 308 based on the updated tuning values 350. The transmission signal based on the updated tuning values 350 may be provided to the feedback receiver to determine whether the adjacent channel leakage ratio (e.g., the transmission tuning metrics 346) of the transmission signal satisfies the adjacent channel leakage ratio threshold.

If the adjacent channel leakage ratio satisfies the adjacent channel leakage ratio threshold, the micro digital signal processor 408 may converge the tuning values of the power amplifier load tuner 308 as the tuning value for adjacent channel leakage ratio, at 347, and may store the tuning values of the power amplifier load tuner 308 in the lookup table of the memory 452. If the adjacent channel leakage ratio fails to satisfy the adjacent channel leakage ratio threshold, the micro digital signal processor 408 may input the adjacent channel leakage ratio into the tuning algorithm 348 to determine updated tuning values 350 in a substantially similar manner as described above (e.g., closed-loop tuning). In an exemplary embodiment, the high speed serial data interface 406 may enable the demodulator 324 to communicate timing windows as to where the micro digital signal processor 408 may perform load impedance tuning (e.g., adjust the impedance of the power amplifier load tuner 308).

In an exemplary embodiment, the modem 402 may include multiple modulators and multiple digital-to-analog converters in the transmission path that are configured to provide outputs to multiple wireless transceivers. Each wireless transceiver may include a micro digital signal processor (DSP) coupled to adjust the impedance of the power amplifier load tuner 308 for a frequency associated with the wireless transceiver. In this exemplary embodiment, the modem 402 may bypass dynamic load impedance matching for multiple active inputs (e.g., for uplink carrier aggregation (ULCA) or multiple-input multiple-output (MIMO) implementations).

The system 400 of FIG. 4 may enable dynamic adjustment of the power amplifier load tuner 308 based on use cases. For example, during voice communications, the system 400 may dynamically adjust the impedance (e.g., the number of active capacitors and/or active inductors in the power amplifier load tuner 308) to improve power added efficiency. During data communications, the system 400 may dynamically adjust the impedance to improve adjacent channel leakage ratio, output power, and linearity. Further, during voice applications with relatively strong data throughput (e.g., global positioning system (GPS) applications), the system 400 may dynamically adjust the impedance to a “compromise” point to achieve relatively high power added efficiency, adjacent channel leakage ratio, output power, and linearity.

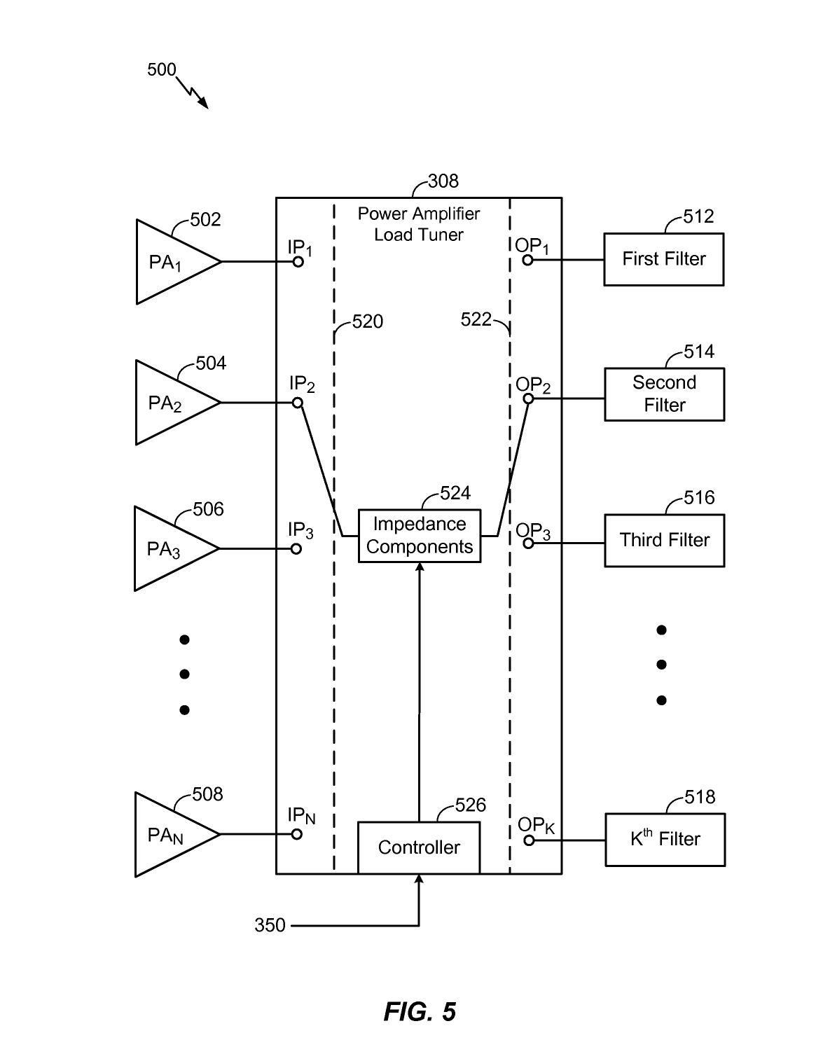

Referring to FIG. 5, an exemplary embodiment of a device 500 that includes the power amplifier load tuner 308 is shown. The device 500 may include the power amplifier load tuner 308, multiple power amplifiers 502-508, and multiple filters 512-518. In an exemplary embodiment, the power amplifiers 502-508 may correspond to the power amplifiers 306 of FIGS. 3-4 and the filters 512-518 may correspond to the filters 310 of FIGS. 3-4.

The power amplifier load tuner 308 may include multiple input ports 520 and multiple output ports 522. Each power amplifier 502-508 may be coupled to a corresponding input port of the power amplifier load tuner 308. For example, a first power amplifier 502 may be coupled to a first input port (IP₁), a second power amplifier 504 may be coupled to a second input port (IP₂), a third power amplifier 506 may be coupled to a third input port (IP₃), and an N^{th} power amplifier 508 may be coupled to an N^{th} input port (IP_{N}). In a similar manner, each filter 512-518 may be coupled to a corresponding output port of the power amplifier load tuner 308. For example, a first filter 512 may be coupled to a first output port (OP₁), a second filter 514 may be coupled to a second output port (OP₁), a third filter 516 may be coupled to a third output port (OP₃), and a K^{th} filter 518 may be coupled to a K^{th} output port (ON.

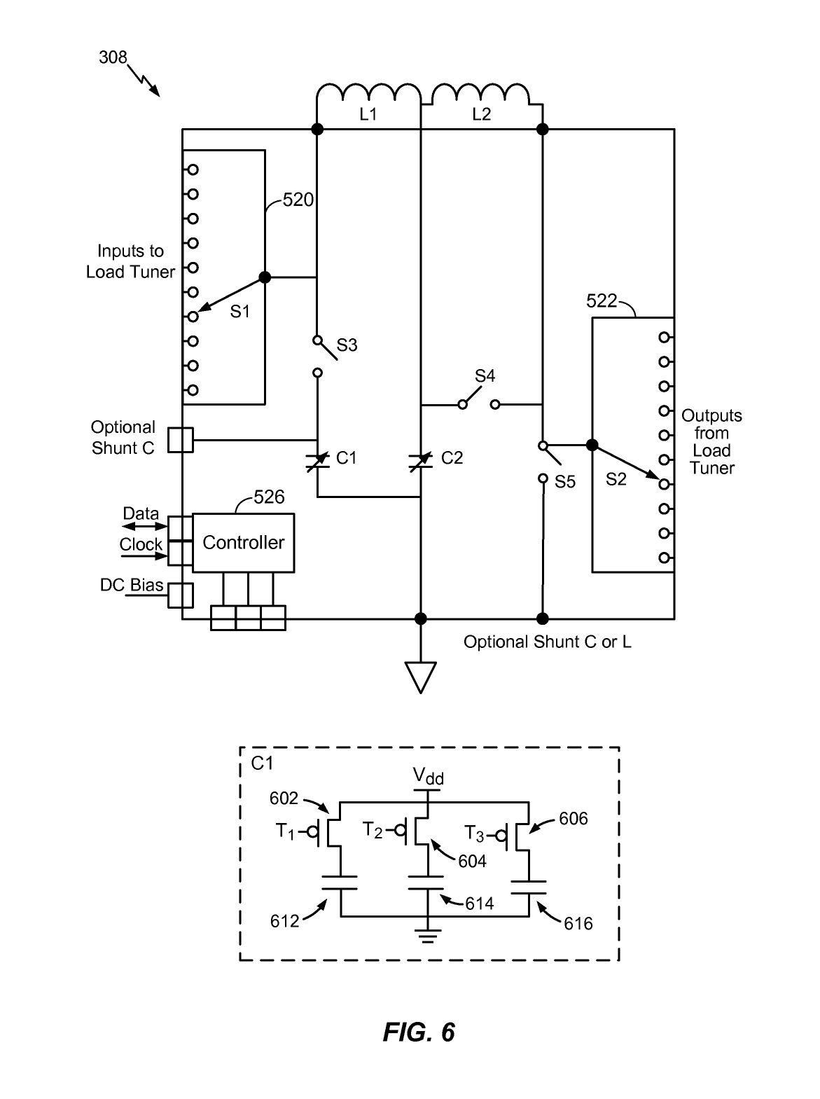

The power amplifier load tuner 308 may also include impedance components 524 (e.g., dynamically adjustable matching components). As explained in further detail with respect to FIG. 6, the impedance components 524 may include one or more capacitors banks and/or one or more inductors. The impedance components 524 may be coupled to one of the power amplifiers 502-508 and to one of the filters 512-518. For example, in the illustrated embodiment, the impedance components 524 are coupled to the second power amplifier 504 and to the second filter 514 to enable transmission over the second transmission frequency (e.g., synchronous port selection). In other embodiments indicative of synchronous port selection, the impedance components may be coupled to the first power amplifier 502 and the first filter 512 to enable transmission over the first transmission frequency, the third power amplifier 506 and the third filter 516 to enable transmission over the third transmission frequency, or the N^{th} power amplifier 508 and the K^{th} filter 518 to enable transmission over the N^{th} transmission frequency.

In an exemplary embodiment of asynchronous port selection, the impedance components 524 are coupled to the first power amplifier 502 and to the second filter 514. For example, the first power amplifier 502 may be capable of transmitting over a bandwidth that spans multiple frequency bands (e.g., the first transmission frequency associated with the first filter 512, the second transmission frequency associated with the second filter 514, the third transmission frequency associated with the third filter 516, etc.). The power amplifier load tuner 308 enables a single power amplifier (e.g., the first power amplifier 502) to connect to a plurality of filters using a single load tuning block (e.g., the impedance components 524) to reduce the number of passive matching components used for each filter and to enable adaptive capability based on different use cases (e.g., voice communication and data communication).

The power amplifier load tuner 308 may also include a controller 526 coupled to receive an input, such as the tuning values 350. The controller 526 may be configured to dynamically adjust the impedance of the power amplifier load tuner 308 based on the tuning values 350. For example, the controller 526 may selectively activate or deactivate capacitors and/or inductors of the impedance components 524 based on the tuning values 350.

The power amplifier load tuner 308 may reduce the number of matching components as compared to a conventional power amplifier load tuner by selectively coupling the impedance components 524 to one of the power amplifiers 502-508 and to a corresponding filter 512-518 based on the transmission frequency. For example, the power amplifier load tuner 308 may use common components to selectively adjust (e.g., couple/decouple) capacitors and/or inductors for different frequency bands and modes of operations (as compared to having a separate group of capacitors and/or inductors for each frequency band and/or mode of operation).

In addition, the power amplifier load tuner 308 may support dynamic adjustment of the impedance components 524 based on use cases (e.g., modes of operations). For example, during voice communications, the controller 526 may dynamically adjust the impedance components 524 to improve power added efficiency. During data communications, the controller 526 may dynamically adjust the impedance components 524 to improve adjacent channel leakage ratio, output power, and linearity. Further, during voice applications with relatively strong data throughput (e.g., global positioning system (GPS) applications), the controller 526 may dynamically adjust the impedance components 524 to a “compromise” point to achieve relatively high power added efficiency, adjacent channel leakage ratio, output power, and linearity.

Referring to FIG. 6, an exemplary embodiment of the power amplifier load tuner 308 is shown. The power amplifier load tuner 308 may include multiple input ports 520 and multiple output ports 522. A first switch (S1) may selectively couple impedance components (as described below) to an input port, and a second switch (S2) may selectively couple impedance components to an output port. In an exemplary embodiment, the first switch (S1) and the second switch (S2) may be coupled to corresponding ports. For example, in the exemplary embodiment, the first switch (S1) is coupled to the seventh input port and the second switch (S2) is coupled to the seventh output port. The first switch (S1) and the second switch (S2) may be controlled by the controller 526.

The power amplifier load tuner 308 may include a third switch (S3) that is controlled by the controller 526. When activated, the third switch (S3) may couple a first capacitor bank (C1) and a second capacitor bank (C2) to the selected ports. The controller 526 may selectively activate capacitors in the first capacitor bank (C1) and selectively activate capacitors in the second capacitor bank (C2) based on the tuning values 350 (e.g., data). For example, the first capacitor bank (C1) may include a first transistor 602, a second transistor 604, and a third transistor 606. In an exemplary embodiment, each transistor 602-606 may be a p-type metal oxide semiconductor (PMOS) transistor. The first transistor 602 may be coupled to a first capacitor 612, the second transistor 604 may be coupled to a second capacitor 614, and the third transistor 606 may be coupled to a third capacitor 616. A gate of the first transistor 602 may be coupled to receive a first tuning signal (T1), a gate of the second transistor 604 may be coupled to receive a second tuning signal (T2), and a gate of the third transistor 606 may be coupled to receive a third tuning signal (T3). When the first tuning signal (T1) has a logical low voltage level, current may propagate through the first transistor 602 to charge (e.g., activate) the first capacitor 612. The second and third transistors 604, 606 may operate in a substantially similar manner with respect to the second and third tuning signals (T2, T3) to charge the second and third capacitors 614, 616, respectively. The third switch (S3) may also couple an optional shunt capacitor to the selected ports.

In an exemplary embodiment, the power amplifier load tuner 308 may also include a first inductor (L1). The first inductor (L1) may increase inductance (e.g., reduce or modify impedance from the power amplifier load tuner 308) to support frequencies within a low band (e.g., approximately 600 MHz to 2.4 GHz). The power amplifier load tuner 308 may also include a fourth switch (S4) that is controlled by the controller 526. When activated, the fourth switch (S4) may couple a second inductor (L2) to the selected ports. The second inductor (L2) may increase inductance to support frequencies within a lower band (e.g., lower than 600 MHz). The power amplifier load tuner 308 may include a fifth switch (S5) that is controlled by the controller 526. When activated, the fifth switch (S5) may couple an optional shunt capacitor and/or an optional inductor to the selected ports.

The power amplifier load tuner 308 may reduce the number of matching components associated with a conventional power amplifier load tuner by dynamically adjusting the load impedance based on data provided to the controller 526. For example, the controller 526 may selectively activate switches (S3-S5) to couple capacitor banks (C1, C2) and/or inductors (L1, L2) to the selected ports to adjust the load impedance. In addition, the controller 526 may selectively couple/decouple one or more capacitors in the capacitor banks (C1, C2) to adjust the impedance, as described above.

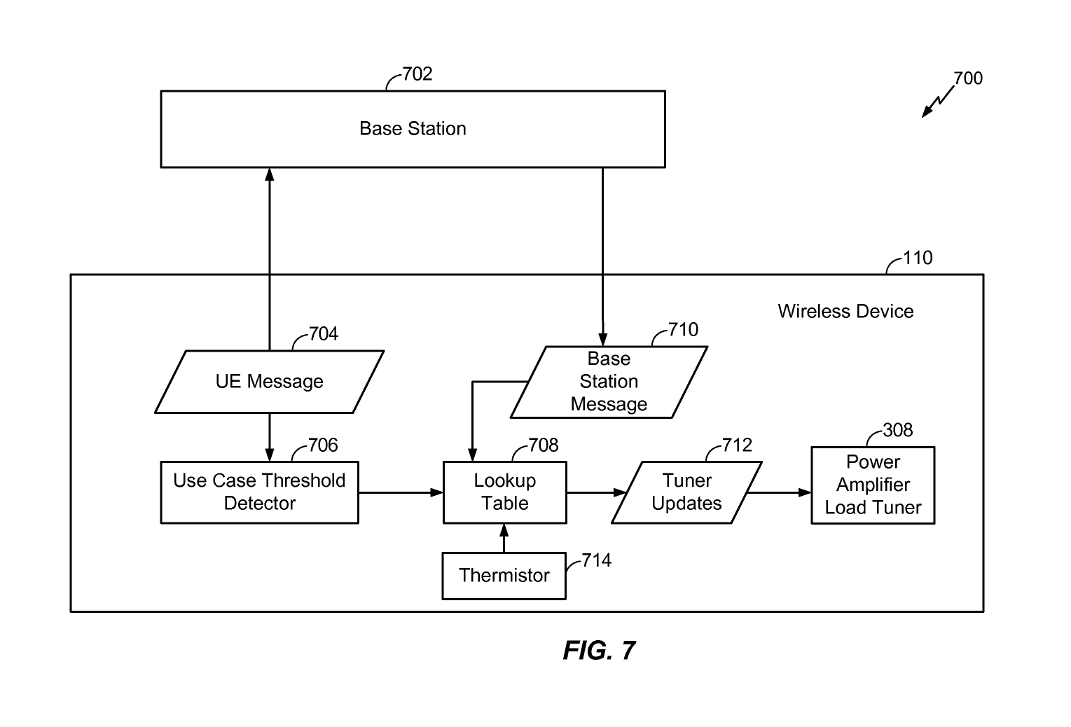

Referring to FIG. 7, a communications system 700 that includes a base station 702 and the wireless device 110 is shown. In an exemplary embodiment, the base station 702 may communicate with the wireless device 110 via a wireless network (not shown). For example, the wireless device 110 may transmit uplink communications (e.g., signals) to the base station 702 via the wireless network, and the base station 702 may transmit downlink communications to the wireless device 110 via the wireless network. In an exemplary embodiment, the base station 702 may be an Evolved Node B (eNodeB) and the wireless device 110 may be a user equipment (UE) according to a Long Term Evolution (LTE) type communication standard.

The wireless device 110 may be configured to generate a UE message 704. In a particular embodiment, the UE message may include a buffer status report. The buffer status report may include information about an amount of pending data in one or more uplink buffers of the wireless device 110. In an exemplary embodiment, the buffer status report may indicate the amount of pending data in the uplink for one or more classes of service (e.g., logical channels in the LTE standard). The UE message 704 may be provided to the base station 702 and to a use case threshold detector 706 in the wireless device 110. In other embodiments, the UE message 704 may include other information to be used by the use case threshold detector 706. For example, the UE message 704 may include information associated with an average data rate used for uplink transmission over the different logical channels, a minimum data rate used for uplink transmissions over the different logical channels, and a maximum data rate used for uplink transmissions over the different logical channels. The UE message 704 may also include information associated with a periodicity of uplink and downlink activity, channel qualities of the different logical channels, a modulation and coding scheme for uplink transmissions, signal-to-noise (SNR) ratios for the different logical channels, Doppler information, or any combination thereof.

The use case threshold detector 706 may be configured to determine a use case based on the UE message 704. For example, the use case threshold detector 706 may determine whether voice communications, data communications, or a combination thereof, is to be transmitted over the wireless network. The use case threshold detector 706 may provide an indication of the use case to a lookup table 708. In an exemplary embodiment, the lookup table 708 may correspond to the lookup table stored in the memory 352 of FIGS. 3-4. In other exemplary embodiments, the wireless device 110 may include multiple lookup tables. For example, the wireless device 110 may include a first lookup table for voice communications, a second lookup table for data communications, and a third lookup table for a hybrid of voice and data communications. The use case threshold detector 706 may select a lookup table (e.g., the first, second or third lookup table) based on the use case determined from the UE message 704, and the wireless device 110 may determine updated tuning values 712 based on the selected lookup table, as described below.

In an exemplary embodiment, the use case threshold detector 706 may provide additional metrics to the lookup table 708 based on the UE message 704. For example, the use case threshold detector 706 may also indicate the average data rate used for uplink transmission over the different logical channels, the minimum data rate used for uplink transmissions over the different logical channels, and the maximum data rate used for uplink transmissions over the different logical channels. The use case threshold detector 706 may indicate the periodicity of uplink and downlink activity, an indication of whether the sleep state has been triggered, channel qualities of the different logical channels, a modulation and coding scheme for uplink transmissions, signal-to-noise (SNR) ratios for the different logical channels, Doppler information, or any combination thereof.

The wireless device 110 may receive a base station message 710 from the base station 702. In a particular embodiment, the base station message 710 may be an uplink grant. The uplink grant may indicate a physical channel allocation (e.g., frequency allocation, power control, and modulation and coding scheme (MCS)) for the wireless device 110. For example, the wireless device 110 may allocate the physical channel resources across the logical channels starting from the highest priority logical channel to the logical channel of least priority (e.g., starting with logical channels for voice communications and ending with logical channels for data communications). In other exemplary embodiments, the logical channel granted to the wireless device 110 may be a logical channel having a lower priority in the UE message 704 (e.g., a logical channel associated with data communications as opposed to a logical channel associated with voice communications). The uplink grant (e.g., the allocated transmission frequency, power control, and MCS) may be provided to the lookup table 708. In an exemplary embodiment, the wireless device 110 may also determine whether any outstanding hybrid automatic repeat request (HARQ) states are present based on the base station message 710.

The wireless device 110 may also determine a temperature of a wireless transceiver (e.g., the transceiver 220 of FIG. 2, the transceiver 222 of FIG. 2, the wireless transceiver 304 of FIG. 3, or the wireless transceiver 404 of FIG. 4). For example, the wireless device 110 may include a temperature-dependent sensing element, such as a thermistor 714 (e.g., a resistor that has a resistance that varies with temperature), to generate the temperature measurements of the wireless transceiver. Temperature measurements may be made at various locations in the wireless device 110 (e.g., the user equipment) for load tuner control. For example, temperature measurements may be made at a power amplifier, a load tuner, a wireless transceiver, a power management integrated circuit (PMIC), etc. The temperature measurements (e.g., temperature readings) may be provided to the lookup table 708, and the wireless device 110 may determine updated tuning values 712 for the power amplifier load tuner 308 based on the temperature measurements. For example, the wireless device 110 may lookup capacitance values stored in the lookup table 708 based on similar temperature measurements and provide the capacitance values to the power amplifier load tuner 308 as updated tuning values 712.

In an exemplary embodiment, based on the use case (and/or other metrics) from the use case threshold detector 706, the allocated transmission frequency from the base station message 710, and the temperature of the wireless transceiver, the wireless device 110 may determine a number of active capacitors and/or a number of active inductors in the power amplifier load tuner 308. For example, the lookup table 708 may store information associated with a number of active capacitors and/or a number of active inductors in the power amplifier load tuner 308 for a corresponding transmission frequency, temperature, and use case. The wireless device 110 may access the lookup table 708 to determine updated tuning values 712 (e.g., the number of active capacitors and/or number of active inductors) based on stored information in the lookup table. The updated tuning values 712 may be sent to the power amplifier load tuner 308 via a digital signal in a substantially similar manner as described with respect to the updated tuning values 350 of FIGS. 3-4. Additionally, the wireless device 110 may be updated via online tuning as described with respect to FIGS. 3-4.

The system 700 of FIG. 7 may enable the wireless device 110 to tune the power amplifier load tuner 308 based on information in the lookup table 708 when a channel is assigned to the wireless device 110, a temperature of the wireless transceiver is measured, and a use case is determined Tuning the power amplifier load tuner 308 based on the information in the lookup table 750 may enable the improved power amplifier performance for a specific transmission frequency and temperature. In addition to the use case threshold detector 706 (or in the alternative), it will be appreciated that any “message” transmitted from the base station 702 to the wireless device 110 or any message generated within the wireless device 110 may be used to tune the power amplifier load tuner 308. For example, the wireless device 110 may generate tuner updates 712 to adjust the impedance of the power amplifier load tuner 308 based on information in one or more messages transmitted from the base station 702 and/or one or more messages generated within the wireless device 110.

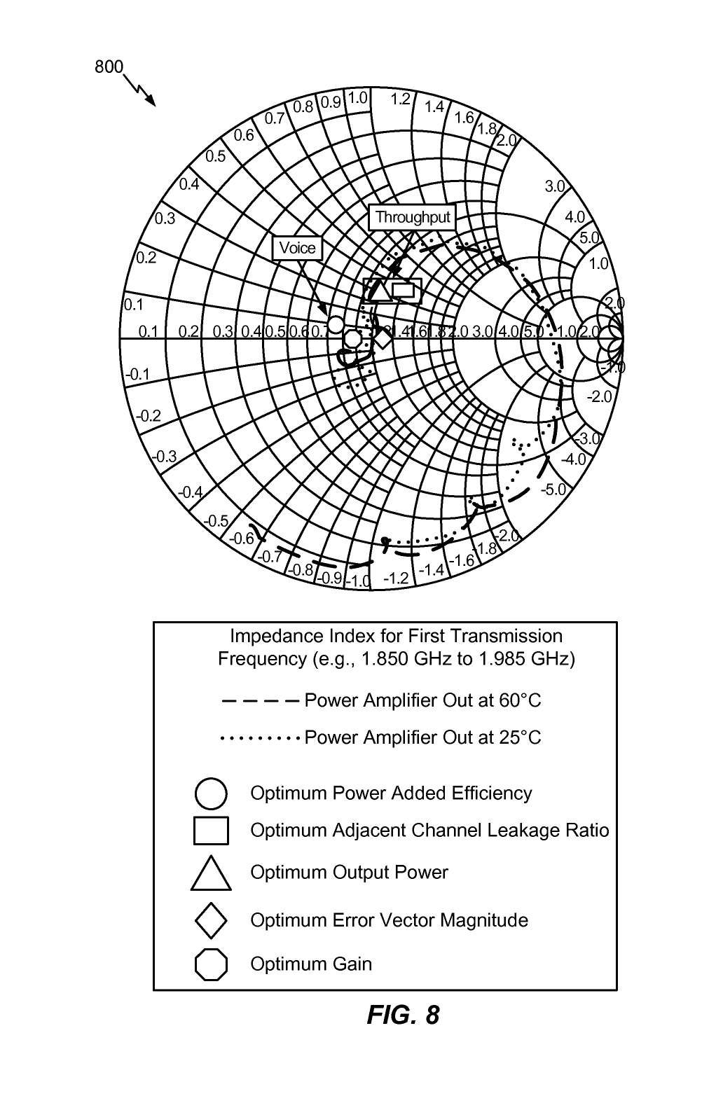

Referring to FIG. 8, a Smith chart 800 that illustrates advantages of a power amplifier load tuner having a dynamically adjustable impedance is shown. For the first transmission frequency (e.g., 1.850 GHz to 1.985 GHz), the Smith chart 800 illustrates locus points corresponding to different impedances that yield tuning transmission metrics. Variations for a power amplifier having an output at 25 degrees Celsius may be depicted using a first trace, and variations for a power amplifier having an output at 60 degrees Celsius may be depicted using a second trace. In addition, shapes may indicate locus points corresponding to different impedances that yield “optimum” tuning metrics. For example, the circle may indicate a locus point corresponding to the impedance of the power amplifier load tuner 308 that yields improved power added efficiency. The rectangle may indicate a locus point corresponding to the impedance of the power amplifier load tuner 308 that yields improved adjacent channel leakage ratio. The triangle may indicate a locus point corresponding to the impedance of the power amplifier load tuner 308 that yields improved output power. The diamond may indicate a locus point corresponding to the impedance of the power amplifier load tuner 308 that yields improved error vector magnitude, and the octagon may indicate a locus point corresponding to the impedance of the power amplifier load tuner 308 that yields improved gain.

The embodiments described above may enable dynamic adjustment of the power amplifier load tuner 308 based on use cases (e.g., modes of operations). For example, during voice communications, the impedance of the power amplifier load tuner 308 may be dynamically adjusted to approximate the impedance of the locus point represented by the circle for improved power added efficiency. During data communications, the impedance of the power amplifier load tuner 308 may be dynamically adjusted to approximate the impedance of the locus points represented by the square or triangle for improved adjacent channel leakage ratio or output power, respectively. Alternatively, the impedance of the power amplifier load tuner 308 may be dynamically adjusted to a “compromise” locus point to achieve relatively high power added efficiency, adjacent channel leakage ratio, output power, error vector magnitude, and gain. Locus points for improved transmission metrics may vary based on the transmission frequency and the temperature at which signals are transmitted. For example, the locus point for improved power added efficiency (e.g., the circle) may differ from the embodiment depicted in FIG. 8 for a different transmission frequency and/or a different temperature.

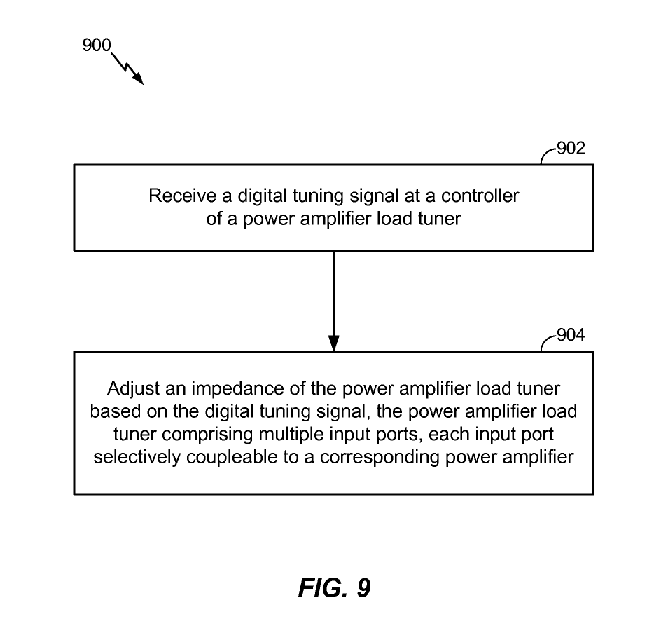

Referring to FIG. 9, a flowchart that illustrates an exemplary embodiment of a method 900 for adjusting an impedance of a power amplifier load tuner is shown. In an illustrative embodiment, the method 900 may be performed using the wireless device 110 of FIGS. 1-2, the system 300 of FIG. 3, the system 400 of FIG. 4, the device 500 of FIG. 5, the power amplifier load tuner 308 of FIG. 6, or any combination thereof.

The method 900 includes receiving a digital tuning signal at a controller of a power amplifier load tuner, at 902. For example, referring to FIG. 3-6, tuning values 350 may be provided to the controller (e.g., the controller 526) of the power amplifier load tuner 308 as a digital signal. The tuning values may be based on transmission metrics of a transmission signal. For example, the modem 302 may be configured to determine whether one or more of the transmission tuning metrics 346 (e.g., power added efficiency, linearity, adjacent channel leakage ratio, output power, error vector magnitude, gain, etc.) satisfy a threshold. If the transmission metric of the transmission signal at the particular frequency satisfies the threshold, the modem 302 may converge the tuning values of the power amplifier load tuner 308 as the tuning value for the transmission metric, at 347, and may store the tuning values of the power amplifier load tuner 308 in a lookup table of a memory 352. If the transmission metric of the transmission signal at the particular frequency fails to satisfy the threshold, the modem 302 may input the transmission metric into a tuning algorithm 348 to determine updated tuning values 350. The controller 526 may receive the updated tuning values as a digital tuning signal.

An impedance of a power amplifier load tuner may be adjusted based on the digital tuning signal, at 904. For example, referring to FIG. 6, the controller 526 may selectively activate switches (S3-S5) to couple capacitor banks (C1, C2) and/or inductors (L1, L2) to the selected ports to adjust the impedance. In addition, the controller 526 may selectively couple/decouple one or more capacitors in the capacitor banks (C1, C2) to adjust the impedance of the power amplifier load tuner 308. The power amplifier load tuner 308 may include multiple input ports 520. Each input port may be selectively coupleable to a corresponding power amplifier (e.g., the power amplifiers 306 of FIGS. 3-4, the power amplifiers 502-508 of FIG. 5, or any combination thereof).

The method 900 of FIG. 9 may reduce the number of matching components associated with a conventional power amplifier load tuner by dynamically adjusting the load impedance based on data provided to the controller 526. In addition, the impedance of the power amplifier load tuner 308 may be dynamically adjusted based on use cases (e.g., modes of operations). For example, during voice communications, the controller 526 may dynamically adjust the impedance of the power amplifier load tuner 308 to improve power added efficiency. During data communications, the controller 526 may dynamically adjust the impedance of the power amplifier load tuner 308 to improve adjacent channel leakage ratio, output power, and linearity. Further, during voice applications with relatively strong data throughput (e.g., global positioning system (GPS) applications), the controller 526 may dynamically adjust the impedance of the power amplifier load tuner 308 to a “compromise” point to achieve relatively high power added efficiency, adjacent channel leakage ratio, output power, and linearity.

In conjunction with the described embodiments, an apparatus includes means for amplifying a signal to be transmitted over a first frequency band of multiple frequency bands. For example, the means for amplifying may include the power amplifiers 254pa, 254pk, 254sa, 254sl of FIG. 2, the power amplifiers 306 of FIGS. 3-4, the power amplifiers 502-508 of FIG. 5, one or more other devices, circuits, modules, or instructions to amplify the signal to be transmitted over the first frequency band, or any combination thereof.

The apparatus may also include means for adjusting a load impedance for the first frequency band based on a tuning signal. For example, the means for adjusting the load impedance may include the power amplifier load tuner 308 of FIGS. 3-6, the controller 526 of FIG. 5, the impedance components of FIGS. 5-6, the capacitor banks (C1, C2) of FIG. 6, the inductors (L1, L2) of FIG. 6, the switches (S3-S5) of FIG. 6, one or more other devices, circuits, modules, or instructions to adjust the load impedance, or any combination thereof.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. In an exemplary embodiment, the tuning algorithm 348 may be implemented using software that is executable by a processor. In another exemplary embodiment, the controller 526 may be implemented using software that is executable by a processor. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal In the alternative, the processor and the storage medium may reside as discrete components in a computing device or user terminal

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. An apparatus comprising:
at least one power amplifier; and
a power amplifier load tuner comprising multiple input ports, a first input port of the power amplifier load tuner selectively coupleable to a corresponding power amplifier of the at least one power amplifier, the power amplifier load tuner having an impedance that is adjustable based on a received tuning signal.

2. The apparatus of claim 1, wherein the power amplifier load tuner further comprises a controller configured to adjust the impedance based on the tuning signal.

3. The apparatus of claim 2, wherein the power amplifier load tuner further comprises:
a capacitor bank, wherein adjusting the impedance of the power amplifier load tuner comprises selectively activating at least one capacitor in the capacitor bank; and
an inductor, wherein adjusting the impedance of the power amplifier load tuner comprises selectively coupling the inductor to the capacitor bank.

4. The apparatus of claim 1, further comprising:
a wireless transceiver coupled to the at least one power amplifier, the wireless transceiver comprising:
a low noise amplifier coupled to amplify a filtered output of the power amplifier load tuner; and
a down-converter and low pass filter coupled to down-convert and filter an output of the low noise amplifier;
a modem coupled to the wireless transceiver, the modem configured to:
determine transmission tuning metrics based on a digitized output of the down-converter and low pass filter; and
determine updated tuning values for the power amplifier load tuner based on the transmission tuning metrics, wherein the tuning signal indicates the updated tuning values.

5. The apparatus of claim 1, further comprising:
a wireless transceiver coupled to the at least one power amplifier, the wireless transceiver comprising:
a low noise amplifier coupled to amplify a filtered output of the power amplifier load tuner;
a down-converter and low pass filter coupled to down-convert and filter an output of the low noise amplifier; and
a processor configured to:
determine transmission tuning metrics based on a digitized output of the down-converter and low pass filter; and
determine updated tuning values for the power amplifier load tuner based on the transmission tuning metrics, wherein the tuning signal indicates the updated tuning values.

6. The apparatus of claim 1, wherein the tuning signal is based on an output of the power amplifier load tuner.

7. The apparatus of claim 1, wherein the tuning signal is based on data stored in a lookup table of a memory or based on data generated during online tuning.

8. The apparatus of claim 1, wherein the tuning signal is generated from circuitry configured to perform self-test operation to determine tuning values for the power amplifier load tuner based on selected metrics.

9. The apparatus of claim 1, wherein the adjustable impedance enables the power amplifier load tuner to change its impedance, and wherein the power amplifier load tuner has a first circuit area that is smaller than a second circuit area of a load tuner that includes separate passive matching components corresponding to each of multiple impedances.

10. An apparatus comprising:
means for amplifying a signal to be transmitted over a first frequency band of multiple frequency bands; and
means for adjusting a load impedance for the first frequency band based on a tuning signal.

11. The apparatus of claim 10, wherein the tuning signal includes a digital signal associated with at least one metric associated with transmission performance of the means for amplifying.

12. The apparatus of claim 10, wherein the tuning signal is associated with at least one metric, and wherein the at least one metric is based on an operating bandwidth, an operating channel frequency, an operating temperature, a resource block configuration, a determination that a transmission is associated with voice communications, or a determination that the transmission is associated with data communications.

13. The apparatus of claim 10, wherein the tuning signal is associated with at least one metric, and wherein the at least one metric is based on messages sent from a base station or messages generated within a wireless device associated with the means for adjusting the load impedance.

14. The apparatus of claim 10, wherein the tuning signal is based on a temperature of a wireless transceiver associated with the means for adjusting the load impedance, a use case for signal transmissions of the means for amplifying, and a transmission frequency of the means for amplifying.

15. The apparatus of claim 14, wherein the temperature of the wireless transceiver is determined using a thermistor, wherein the use case for signal transmissions is determined by a use case threshold detector, and wherein the transmission frequency is determined based on an uplink grant received by the wireless transceiver from a base station.

16. The apparatus of claim 10, wherein the means for adjusting the load impedance comprises means for selectively activating at least one capacitor in a capacitor bank of the means for adjusting the load impedance.

17. The apparatus of claim 16, wherein the means for adjusting the load impedance comprises means for selectively coupling an inductor to the capacitor bank.

18. A method comprising:
receiving a tuning signal at a controller of a power amplifier load tuner; and
adjusting an impedance of the power amplifier load tuner based on the tuning signal, the power amplifier load tuner comprising multiple input ports, each input port selectively coupleable to a corresponding power amplifier.

19. The method of claim 18, wherein the impedance of the power amplifier load tuner is adjusted based on at least one metric associated with transmission performance of a wireless device.

20. The method of claim 18, wherein the tuning signal is based on a mode of operation, and wherein the mode of operation corresponds to voice communications or data communications.
